(19) United States
(12) Patent Application Publication
(10) Pub. No.: US 2003/0048155 A1
(43) Pub. Date: Mar. 13, 2003

(54) Low pass for an adsl frequency filter

(76) Inventor: Dirk Heumann, Nidderau (DE)

Correspondence Address: JOHN S. PRATT, ESQ, KILPATRICK STOCKTON, LLP, 1100 PEACHTREE STREET, SUITE 2800, ATLANTA, GA, 30309, US

(21) Appl. No.: 09/913,306

(22) PCT Filed: Dec. 7, 2000
(86) PCT No.: PCT/EP00/12333

(30) Foreign Application Priority Data
Dec. 10, 1999 (DE) 199 59 724.3

(51) Int. Cl. H03H 7/00

(52) U.S. Cl. 333/167

(57) ABSTRACT

The invention relates to a low pass filter (7′) which is adapted to a complex terminator wherein at least one inductor (17) is provided with a parallel-connected real resistor (18) in order to increase reflection dampening in the series arm. In the low pass filter (7′) is provided with at least one inductor (17) series arm which is not connected in parallel to a real resistor.

The invention relates to a filter arrangement with series arms, disposed pairwise, extending between connections of the filter arrangement and having inductors, and with at least one parallel arm extending between the series arms and having at least one capacitor.

Filter arrangements of this type are known from the handbook, Anatol I. Zverev, “Handbook of Filter Synthesis”, 1967. The known filter arrangements can be combined to form frequency filters. If, for example, a low pass and a high pass are connected in parallel, high-frequency signals are conducted over the filter arm provided with a high pass and low-frequency signals are conducted over the filter arm provided with a low pass. In the ADSL telecommunications system the connection between an ADSL-capable digital local exchange and the ADSL modem, which is at the same time the network terminator on the subscriber side, is made via a public two-wire line. In this case ADSL stands for “Asymmetric Digital Subscriber Line”. At the same time POTS and ISDN connections can run over the same two-wire line. In this case POTS stands for “Plain Old Telephone System” and ISDN for “Integrated Services Digital Network”. The separation and transmission of the low-frequency POTS or ISDN components from the ADSL components is caused by a filter which sits at the ends of the public two-wire lines. In this case the low-frequency POTS or ISDN components are directed via a low pass into a low pass arm while the high-frequency ADSL components are directed via a high pass into a high pass arm. A low pass suitable for use in an ADSL filter must meet certain requirements regarding transmission function, group delay distortion, and reflection damping. In the transmission range as high a reflection damping as possible is strived for in particular. For example, the reflection damping in the POTS transmission range should be from 200 Hz to 4 kHz>18 dB and 16 kHz>14 dB. The known filters do not meet these requirements.

A known filter arrangement has several filter stages connected in tandem. Furthermore, the symmetric filter arrangement has two series arms each of which consists of several inductors connected in series. The filter stages each include one of the inductors of one series arm and one of the inductors of the other series arm as well as a parallel arm connected between the series arms, said parallel arm having two inductors and one capacitor disposed therebetween.

Proceeding from the state of the art, the objective of the invention is to provide a filter arrangement with improved reflection damping which also satisfies the requirements regarding transmission function and the group delay distortion.

This objective is realized by a filter arrangement which has series arms extending between connections of the filter arrangement and having inductors. Furthermore, the filter arrangement has at least two filter stages to each of which different inductors of the series arms are assigned and of which at least one filter stage has a parallel arm extending between two of the series arms and having at least one capacitor. Series arm inductors belonging to at least one but not all the filter stages are disposed in filter modules, each of which includes at least one inductor with a real resistor connected in parallel to the inductor.

In the case of a filter arrangement with, for example, 4 connections, that is, with two series arms, two inductors of the two series arms and belonging to the same filter stage of a traditional filter arrangement are thus replaced in the case of a filter arrangement according to the invention by the filter modules. In the case of a filter arrangement with, for example, 6 connections, that is, with three series arms, one inductor of each series arms and belonging to the same filter stage of a traditional filter arrangement is thus replaced in the case of a filter arrangement according to the invention by the filter module. In this case three inductors of the three series arms are replaced by the filter modules.

In the at least one filter stage a parallel arm is connected between each two series arms. In the case of three series arms the filter stage has three parallel arms. In the case of two series arms the filter stage has one parallel arm.

Due to the real resistor connected in parallel in the filter module, the terminator of the filter arrangement can be adapted to a complex line resistance so that a high reflection damping in the operating range results for the filter arrangement. Since not all the filter stages have such filter modules the insertion loss, that is, the energy loss in the filter arrangement is not very high.

In order to minimize the insertion loss, preferably only one filter stage has said filter module. It has been shown that the reflection damping is already sharply increased in the case of filter stages having only one filter module.

It lies in the scope of the invention to provide more than one filter stage which has said filter module.

The complex terminator can be represented by ohmic resistors with the values R1 and R2 where a capacitor is connected in parallel to the ohmic resistor with the value R2. If R1 is significantly smaller than R2, then the filter module has, for the reduction of the insertion loss, preferably only one inductor. This inductor is connected in parallel to the resistor.

If R1 is not significantly smaller than R2, then the filter module includes, to increase reflection damping, series-connected inductors with a real resistor connected in parallel to one of the inductors.

To further increase the reflection damping an additional real resistor can be connected in parallel to one inductor of a parallel arm. Also additional parallel arms can be transformed in this manner.

The series arms are preferably set up symmetrically. If, for example, one filter stage has two inductors for the same series arm, then the filter stage has two corresponding inductors for every other series arm.

Preferably the corresponding inductors of the series arms are each wound about the same magnet core. Thereby these inductors are coupled to one another.

The parallel arm is, for example, formed by a series connection of inductors and capacitors. For example, the parallel arm is formed by two inductors between which one capacitor is disposed. If such a parallel arm is transformed, then an additional real resistor is connected in parallel to each of the two inductors.

The inductors in the parallel arm are preferably formed by windings wound on a common magnet core.

In the following the invention is described with the aid of the accompanying drawings. Shown are:

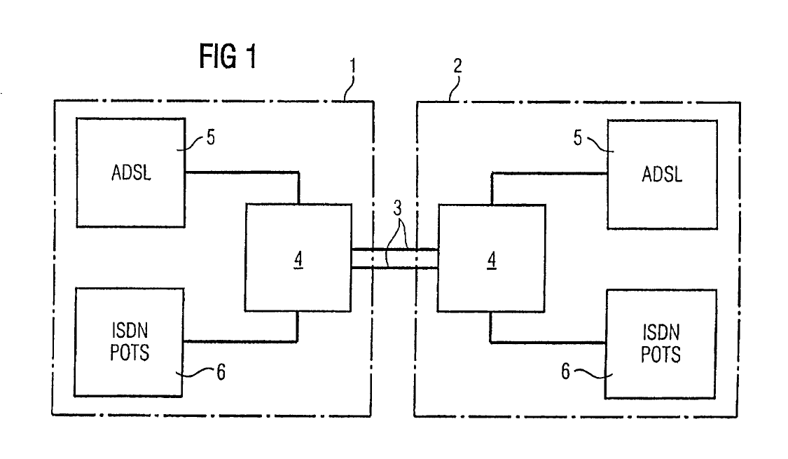

FIG. 1 an overview of the connection between a local exchange and a network terminator on the subscriber side;

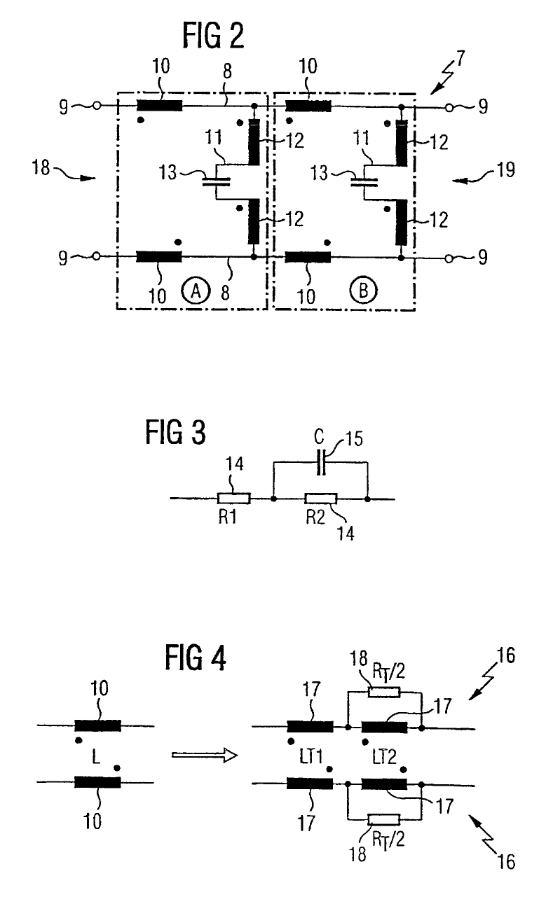

FIG. 2 a traditional low-pass filter arrangement composed of inductors and capacitors;

FIG. 3 an equivalent circuit diagram for the complex line resistance of the public two-wire line,

FIG. 4 a representation of the transformation necessary for the conversion of the traditional low-pass filter arrangement of FIG. 2; and

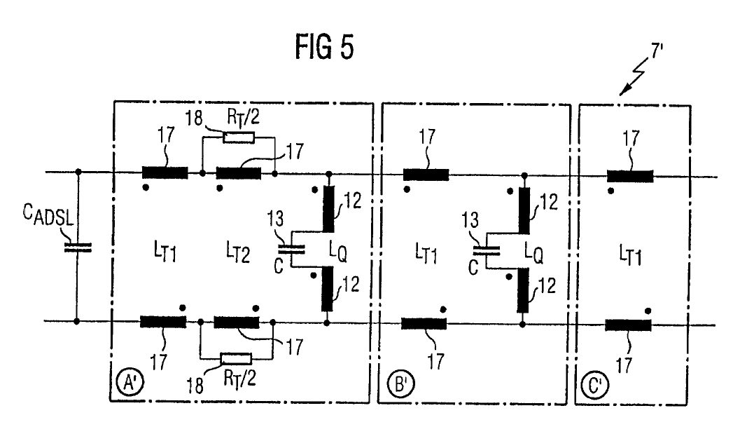

FIG. 5 a first low-pass filter which is adapted to the complex line resistance of FIG. 3.

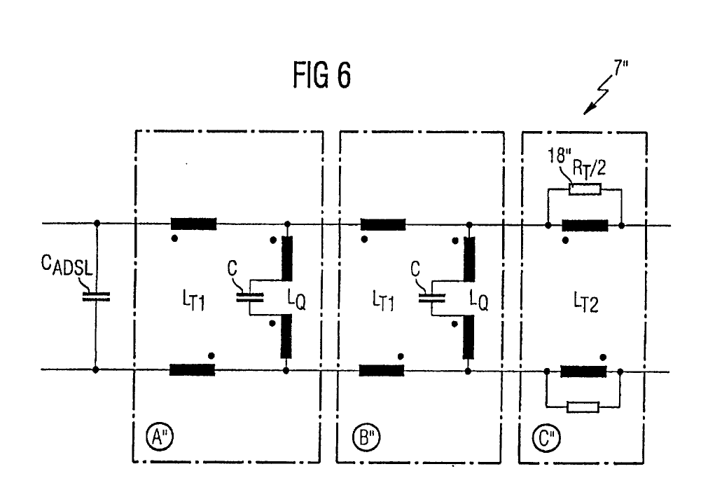

FIG. 6 a second low-pass filter which is adapted to the complex line resistance of FIG. 3.

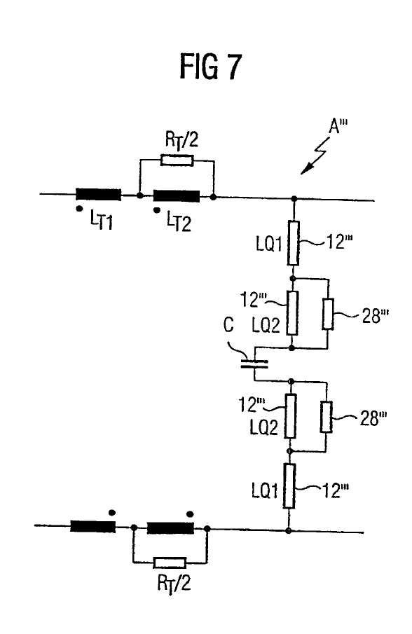

FIG. 7 a filter stage of a third low-pass filter which is adapted to the complex line resistance of FIG. 3.

FIG. 1 shows a schematic representation of the connection between a local exchange 1 and a network terminator 2 on the subscriber side, which are connected to one another via a public two-wire line 3. At the end of the two-wire line 3 frequency filters 4 are provided. The high-frequency ADSL signals running over the public two-wire line 3 are directed by the frequency filters 4 into an ADSL arm 5 while the low-frequency POTS and ISDN signals are directed by the frequency filters 4 into a POTS/ISDN arm 6 respectively. A low-pass filter is expediently disposed at the input of the POTS/ISDN arm 6.

FIG. 2 shows a traditional low-pass filter conditionally suitable for use in the POTS/ISDN arm 6, said low-pass filter being adapted to a real terminator. The low-pass filter 7 is a symmetrical fourth-order filter and has series arms 8 disposed pairwise which extend between connections 9 of the low-pass filter 7. Series inductors 10 are disposed in the series arms 8. Each two of the inductors 10 facing one another in the circuit diagram in FIG. 2 belong to a filter stage A, B and are formed in this case by coils wound on a common magnet core with the same winding sense. Between the series arms 8 parallel arms 11 are disposed each of which belongs one of the filter stages A, B and have the two parallel inductors 12 and a capacitor 13 disposed between the parallel inductors 12. The parallel inductors 12, each present in each parallel arm 11, are formed by coils wound on a common magnet core with the same winding sense. Through the combination of the capacitor 13 and the parallel inductors 12 present in the parallel arms 11 zeroes of the transmission function are formed and the drop-off of the transmission function above a limiting frequency is amplified.

The low-pass filter 7 represented in FIG. 2 is designed for a real terminator and does not have the capacity to meet the rigorous requirements on reflection damping in the case of a complex line resistance.

The line resistance of the public two-wire line 3 for the limiting case of small frequencies is illustrated by an equivalent circuit diagram in FIG. 3. The terminator can be represented by ohmic resistors with the values R1 and R2, where a capacitor 15 with the value C is connected in parallel to the ohmic resistor 14 with the value R2. Below the following is supposed to apply for the complex resistor of the public two-wire line 3:

$$Z = R1 + R2 ‖ \frac{1}{i ω C} \qquad ( 1 )$$

In order to now convert a low-pass filter 7 designed for a real terminator R into a low-pass filter which is completely adapted to the complex terminator of the public two-wire line 3 it is necessary, as represented in FIG. 4, to replace the inductors 10 in the series arm 8 by modules 16, each of which has two inductor elements 17 and one real resistor element 18 connected in parallel to one of the inductor elements 17.

The conversion performed can be based on the following:

Let the low-pass filter 7 of FIG. 2 be considered, said low-pass filter having a real resistance

R−\sqrt{Z₀·Z_{G}} (2)

where Z₀ is the impedance of the low-pass filter 7 with an open end and Z_{G} is the impedance of the low-pass filter 7 with a short-circuited end. Now in order to passively transform the low-pass filter 7 for the complex resistor, equation (2) is multiplied by the factor Z/R. The following expression then results:

$$Z = \sqrt{\frac{Z}{R} \cdot {Z}_{O} \frac{Z}{R} \cdot {Z}_{G}} \qquad ( 3 )$$

In the case of an arbitrary 4-pole filter arrangement according to FIG. 2, for example, the impedance Z₀ results as total impedance between the connections 9 forming the one input 18 in the case of open connections 9 forming one input 19. The total impedance Z₀ then results in the case of series connection as a sum of impedance values or in the case of parallel connection as the inverse of the sum of inverted impedance values. The same applies for the calculation of the total impedance Z_{G} which results as the impedance between the connections 9 on the input side in the case of short-circuited connections 9 on the output side. According to the distributive law the transformation factor Z/R can be introduced so that the transformation of the entire low-pass filter 7 reduces to a transformation of the individual impedances forming the entire low-pass filter 7. For the inductors with the value L a transformed impedance

$${Z}_{T r afo} ( i ω L ) = ( R1 + R2 ‖ \frac{1}{i ω C} ) \frac{i ω L}{R} \qquad ( 4 )$$

then results. This expression can be converted into

Z_{Trafo}(iΩL)=iΩL_{T1}+iΩL_{T2}∥R_{T} (5)

with

$$\begin{matrix}{L}_{T1} = \frac{R1}{R} \cdot L & ( 6 ) \\ {L}_{T2} = \frac{R2}{R} \cdot L & ( 7 ) \\ {R}_{T} = \frac{L}{C R} & ( 8 )\end{matrix}$$

If one takes into account that in the low-pass filter 7 of FIG. 2 inductors facing one another are formed by reactance coils with the same winding sense on a common magnet core, the transformation represented in FIG. 4 finally results. Let one observe that in this case the series inductors 10 are not independent but rather in this case are coils wound on a common magnet core, said coils having the inductance value L in common. In the same manner inductor elements 17 are coils wound on a common magnet core, said coils having together the value L_{T1} and L_{T2}.

It has been shown that a sharp increase of the reflection damping is already achieved in the case of a transformation of inductors 10 of only one filter stage A, B.

A first low-pass filter 7′ transformed only in parts of the series arms 8 of a first filter stage A′ then has the appearance represented in FIG. 5. The exemplary embodiment represented in FIG. 5 of the first filter 7′ almost completely adapted to a complex terminator is a sixth-order filter with three filter stages A′, B′, C′. The high pass leading to the ADSL arm is represented by the capacitor C_{ADSL}. Possible numerical values in order to adapt the first low-pass filter 7′ to a complex terminator with R1=220 Ω, R2=820 Ω, and C=115 nF are given in Table 1:

TABLE 1

| Component | Stage | Value | |
|---|---|---|---|
| C_{ADSL} | | 6,8 | nF |
| L_{T1} | A′ | 697 | μH |
| L_{T2} | A′ | 2598 | μH |
| R_{T} | A′ | 27,5 | Ω |
| L_{Q} | A′ | 72 | μH |
| C | A′ | 11,7 | nF |
| L_{T1} | B′ | 1088 | μH |
| L_{Q} | B′ | 41 | μH |
| C | B′ | 10,5 | nF |
| L_{T1} | C′ | 574 | μH |

Let it be noted that the values of the individual coupled series inductors 17 are each equal to L_{T1}/4 or L_{T2}/4. In the same manner the values of the individual coupled parallel inductors 12 are equal to L_{Q}/4.

Alternatively, the second or the third filter stage can be transformed. Also combinations of filter stages, for example the first and the second filter stage, can be transformed.

In a second exemplary embodiment represented in FIG. 6 only one third filter stage C″ is transformed but not a first filter stage A″ and not a second filter stage B″. An additional difference between this and the first exemplary embodiment consists of the fact that since R1, with a value of 220 ohms, is significantly smaller than R2, which has a value of 820 ohms, series inductors which are not connected in parallel to the resistor 18″ are omitted in the filter modules of the third filter stage C″. Possible numerical values in order to adapt the second low-pass filter 7′ to a complex terminators are given in Table 2.

TABLE 2

| Component | Stage | Value | |
|---|---|---|---|
| C_{ADSL} | | 28 | nF |
| L_{T1} | A″ | 8,84 | mH |
| L_{Q} | A″ | 378 | μH |
| C | A″ | 43 | nF |
| L_{T1} | B″ | 10,2 | mH |
| L_{Q} | B″ | 244 | μH |
| C | B″ | 38 | nF |
| L_{T2} | C″ | 12,32 | mH |
| R_{T} | C″ | 78 | Ohm |

[for data see original noting that a comma in a German number is equivalent to a decimal point in an English number, i.e, 6,8 in German means 6.8 in English.]

For a good reflection damping it is sufficient if inductors 10 are transformed in the series arms 8. The reflection damping can however be further improved by also drawing on inductors 12 in the parallel arms 11 of the transformation represented in FIG. 4. FIG. 7 shows a filter stage A′″ of a third filter with a parallel inductor 12′″ transformed by an additional real resistor 28′″.

The capacitors 13 in the parallel arms 11 cannot be transformed with Z/R, since the corresponding impedance functions are not two-pole functions, for the resulting impedance functions have zeroes in the right plane of the complex S-plane. Thus, the resulting impedance function cannot be divided into individual components. The capacitors 13 in the parallel arms 11 play a role for reflection damping only in the very low-frequency range since high frequencies pass through them. If the values for the capacitors 13 lie below a maximal value, they must not be taken into account. To that extent it is sufficient to transform only the inductors.

1. Filter arrangement with series arms (8) extending between connections (9) of the filter arrangement and having inductors (17) and with at least two filter stages (A′, B′, C′) to each of which different inductors (17) of the series arms (8) are assigned and of which at least one filter stage (A′, B′) has a parallel arm (11) extending between two of the series arms (8) and having at least one capacitor (13) characterized by the fact that inductors (17) of the series arms (8) and belonging to at least one but not all the filter stages (A′) are disposed in filter modules (16) which include at least one inductor (17) with a real resistor (18) connected in parallel to the inductor (17).

2. Filter arrangement according to claim 1 characterized by the fact that the filter modules (16) each include series-connected inductors (17) with a real resistor (18) connected in parallel to the inductors (17).

3. Filter arrangement according to claim 1 or 2 characterized by the fact that in the case of the present series arms (8) the arrangement of the filter modules (16) and the inductors (17) agree.

4. Filter arrangement according to one of the claims 1 to 3 characterized by the fact that each parallel arm (11) is formed by a series connection of inductors (12) and capacitors (13).

5. Filter arrangement according to claim 4 characterized by the fact that each parallel arm (11) is formed by two inductors (12) between which one capacitor (13) is disposed

6. Filter arrangement according to one of the claims 3 to 5 characterized by the fact that the corresponding inductors (17) of the series arms (8) are formed by windings wound on a common magnet core.

7. Filter arrangement according to one of the claims 4 to 6 characterized by the fact that the corresponding inductors (12) in the parallel arm (11) are formed by windings wound on a common magnet core.

8. Filter arrangement according to one of the claims 4 to 7 characterized by the fact that the inductors (12′″) of the parallel arm are each connected in parallel to an additional real resistor (18′″).
